(19) United States
(12) Patent Application Publication
(10) Pub. No.: US 2025/0135511 A1
(43) Pub. Date: May 1, 2025

(54) FILM-ATTACHED SUPPORT FRAME, SUPPORT FRAME, AND METHOD OF TREATING SUPPORTED OBJECT

(71) Applicant: DISCO CORPORATION, Tokyo (JP)

(72) Inventor: Kazuma SEKIYA, Tokyo (JP)

(21) Appl. No.: 18/910,129

(22) Filed: Oct. 9, 2024

(30) Foreign Application Priority Data
Oct. 27, 2023 (JP) 2023-184466

(51) Int. Cl. B08B 3/10; B08B 13/00

(52) U.S. Cl. CPC B08B 3/10; B08B 13/00

(57) ABSTRACT

There is provided a film-attached support frame including a metal support frame having an opening defined therein and a film affixed to the support frame in covering relation to the opening. The support frame includes a first surface with which the film is in contact, a second surface that is opposite to the first surface, and a third surface joined to both the first surface and the second surface and defining the opening that is open in both the first surface and the second surface. The third surface has a portion inclined to the first surface such that the length of the opening along a direction parallel to the first surface is larger along the second surface than along the first surface.

### BACKGROUND OF THE INVENTION

### Field of the Invention

The present invention relates to a film-attached support frame, a support frame, and a method of treating a supported object.

### Description of the Related Art

When a process such as a cutting process or a laser beam process, for example, is to be performed on a workpiece such as a semiconductor wafer, the workpiece, which may also be referred to as a “supported object,” is supported on a support frame. The support frame includes a ring frame having an opening defined centrally therein. The support frame has a surface to which a film is affixed in covering relation to the opening in the frame. The film is also affixed to the workpiece that is placed in the opening. The support frame, the film, and the workpiece are thus integrally combined into a frame unit. The frame unit is introduced into a processing apparatus where the workpiece is processed (see, for example, JP 2020-178102A).

The processing apparatus that processes the workpiece includes a processing unit for processing the workpiece and a spinner cleaning unit for cleaning the workpiece. The spinner cleaning unit includes a holding table for holding the workpiece and a cleaning unit for cleaning the workpiece by supplying a cleaning liquid to the workpiece that is held on the holding table. The holding table has an upper surface acting as a holding surface that applies a negative pressure to the workpiece to attract the workpiece under suction to the holding surface. The holding table is rotatable about its central axis that extends perpendicularly through the holding surface.

After the workpiece has been processed by the processing unit, the workpiece is cleaned and dried by the spinner cleaning unit. In the spinner cleaning unit, the workpiece is held on the holding table with the film interposed therebetween. While the holding table is rotating about its central axis, the cleaning liquid is applied to the workpiece of the frame unit, spin-cleaning the workpiece. Thereafter, while the holding table is still rotating about its central axis, air is ejected to the workpiece, spin-drying the workpiece (see, for example, JP 2021-145089A).

### SUMMARY OF THE INVENTION

As described above, after liquid, i.e., the cleaning liquid, is applied to the workpiece, a drying process such as the spin-drying process is performed on the workpiece. In the spin-drying process, the liquid remaining on the workpiece is expelled from the workpiece, i.e., the frame unit, under centrifugal forces generated by the rotation of the holding table.

The support frame has a first surface to which the film is affixed, a second surface opposite the first surface, and a third surface, i.e., an inner circumferential surface, that defines the opening that extends through the support frame and that is open in both the first surface and the second surface. Since the third surface extends perpendicularly to the first surface and the second surface, the third surface provides a barrier against the cleaning liquid that remains on the workpiece after the spin-cleaning process and flows outwardly on the frame unit under centrifugal forces in the spin-drying process. In other words, the third surface tends to obstruct the cleaning liquid in its way to be discharged from the frame unit in the spin-drying process. As a result, the cleaning liquid is liable to remain on the surface of the film near the third surface of the support frame.

The cleaning liquid remaining on the surface of the film is likely to be scattered around due to vibrations of the frame unit at the time when the frame unit is delivered and deposited on the workpiece secured to the film and the surfaces of other workpieces stored nearby. When the cleaning liquid thus deposited on the surfaces of those workpieces is subsequently dried, it leaves blemishes on the workpieces, spoiling the appearance of the workpieces. In a case where a liquid chemical such as an etching liquid is used as the cleaning liquid, if it remains on the film, it tends to erode the film.

It is therefore an object of the present invention to provide a film-attached support frame and a support frame that have a structure for more easily discharging liquid that has been used to treat a supported object supported on the support frame by a film out of the supported object and the film and for making the liquid less liable to remain on the supported object and the film than heretofore, and a method of processing the supported object using the support frame.

In accordance with an aspect of the present invention, there is provided a film-attached support frame including a metal support frame having an opening defined therein and a film affixed to the support frame in covering relation to the opening, in which the support frame includes a first surface with which the film is in contact, a second surface that is opposite to the first surface, and a third surface joined to both the first surface and the second surface and surrounding the opening that is open in both the first surface and the second surface, and in which the third surface has a portion inclined to the first surface such that a length of the opening along a direction parallel to the first surface is larger along the second surface than along the first surface.

Preferably, the portion includes a first portion closer to the first surface and a second portion closer to the second surface, and an angle formed between the first portion and the first surface and an angle formed between the second portion and the first surface are different from each other.

Preferably, the angle formed between the first portion and the first surface is smaller than the angle formed between the second portion and the first surface.

Preferably, the third surface is liquid-repellent or lyophilic.

In accordance with another aspect of the present invention, there is provided a metal support frame having an opening defined therein, including a first surface with which a film is to be in contact when in use, a second surface that is opposite to the first surface, and a third surface joined to both the first surface and the second surface and defining the opening that is open in both the first surface and the second surface, in which the third surface has a portion inclined to the first surface such that a length of the opening along a direction parallel to the first surface is larger along the second surface than along the first surface.

Preferably, the portion includes a first portion closer to the first surface and a second portion closer to the second surface, and an angle formed between the first portion and the first surface and an angle formed between the second portion and the first surface are different from each other.

Preferably, the angle formed between the first portion and the first surface is smaller than the angle formed between the second portion and the first surface.

Preferably, the third surface is liquid-repellent or lyophilic.

In accordance with a further aspect of the present invention, there is provided a method of treating a supported object supported on a film using a support frame having an opening defined therein and including a first surface with which the film is to be in contact when in use, a second surface that is opposite to the first surface, and a third surface joined to both the first surface and the second surface and defining the opening that is open in both the first surface and the second surface, the method including a frame unit forming step of forming a frame unit including the support frame, the film, and the supported object by affixing the film to the first surface of the support frame in covering relation to the opening and affixing the film to the supported object disposed in the opening, wherein the third surface of the support frame has a portion inclined to the first surface such that a length of the opening along a direction parallel to the first surface is larger along the second surface than along the first surface, after the frame unit forming step, a treating step of treating the supported object with liquid by supplying the liquid to the supported object, and after the treating step, a discharging step of discharging the liquid remaining on the supported object or the film via the third surface by rotating the frame unit about an axis extending through the opening.

With the film-attached support frame, the support frame, and the method of treating a supported object according to the respective aspects of the present invention, the third surface of the support frame has a portion inclined to the first surface such that the length of the opening along a direction parallel to the first surface is larger along the second surface than along the first surface. Inasmuch as the third surface has a portion inclined to the first surface, it allows liquid such as a cleaning liquid used to treat, i.e., clean, the supported object or a workpiece, to travel easily along the third surface out of the frame unit under centrifugal forces generated in a subsequent spin-drying process for drying the supported object. Consequently, after the supported object has been dried, the liquid is less liable to remain on the supported object and the film.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a first example of a frame unit;

FIG. 2 is a cross-sectional view of the first example of the frame unit;

FIG. 3 is a perspective view, partly broken away, schematically illustrating a cleaning apparatus;

FIG. 4 is a cross-sectional view of the frame unit and other parts in a discharging step;

FIG. 5 is a cross-sectional view of a second example of the frame unit; and

FIG. 6 is a cross-sectional view of a third example of the frame unit.

### DETAILED DESCRIPTION OF THE PREFERRED EMBODIMENT

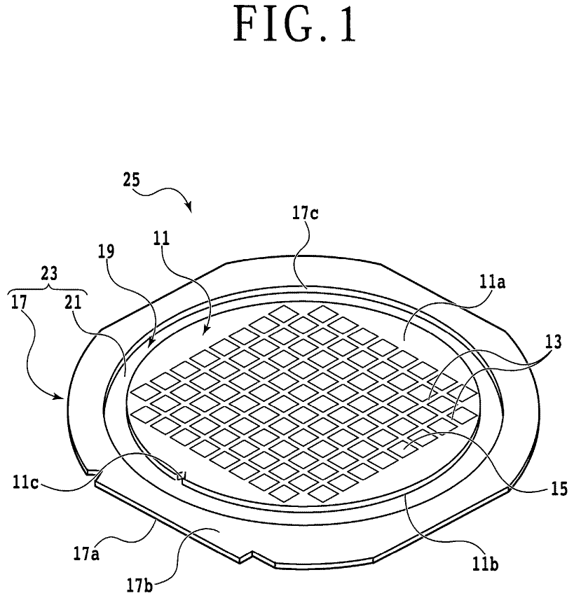

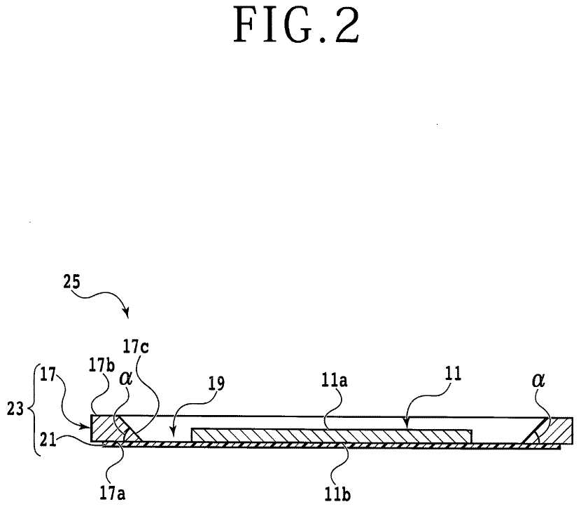

A preferred embodiment of the present invention will be described below with reference to the accompanying drawings. FIG. 1 illustrates a first example of a frame unit 25 in perspective, and FIG. 2 illustrates the first example of the frame unit 25 in cross section. As illustrated in FIG. 1, the frame unit 25 includes a supported object 11 and a film-attached support frame 23 that supports the supported object 11. Specifically, the film-attached support frame 23 includes a support frame 17 of a metal material and a film 21 affixed to the support frame 17. Therefore, the frame unit 25 is made up of the supported object 11, the film 21, and the support frame 17.

The supported object 11, which may also be referred to as a “workpiece,” includes a disk-shaped wafer made of a semiconductor material such as silicon, for example. The supported object 11 is of a disk shape having a substantially circular first surface, i.e. face side, 11a and a substantially circular second surface, i.e., reverse side, 11b opposite the first surface 11a. The supported object 11 has a notch 11c defined in an outer circumferential edge, i.e., a marginal edge, thereof for representing the crystal orientation of the supported object 11.

However, the supported object 11 may be of any of other shaped than the illustrated shape. The supported object 11 may have an orientation flat defined in the outer circumferential edge thereof, rather than the notch 11c. Furthermore, the supported object 11 may be free of the notch 11c or the orientation flat.

A grid of projected dicing lines 13 are established on the first surface 11a of the supported object 11. The projected dicing lines 13 demarcate a plurality of areas on the first surface 11a, and respective devices 15 such as integrated circuits (ICs) are constructed respectively in the demarcated areas. The supported object 11 will be divided along the projected dicing lines 13 into individual device chips having the respective devices 15, by a cutting blade or a laser beam.

The support frame 17 of the film-attached support frame 23 is made of a metal material such as stainless steel (SUS) or aluminum, for example. The support frame 17 is of an annular plate shape having an opening 19 defined centrally therein. The support frame 17 has a first surface 17a, a second surface 17b opposite (i.e., facing away from) the first surface 17a, and a third surface 17c joined to both the first surface 17a and the second surface 17b. The third surface 17c defines the opening 19 and extends in surrounding relation thereto. The opening 19 extends through the support frame 17 and is open in both the first surface 17a and the second surface 17b.

As illustrated in FIG. 2, the third surface 17c has a portion inclined to the first surface 17a such that the length of the opening 19 along a direction parallel to the first surface 17a is larger along the second surface 17b than along the first surface 17a. Providing the opening 19 is of a circular shape, the third surface 17c has a portion inclined to the first surface 17a such that the diameter of the opening 19 is larger along the second surface 17b than along the first surface 17a. Specifically, the third surface 17c intersects with the first surface 17a at an acute angle. Stated otherwise, the support frame 17 is of an annular shape formed by removing a frustoconical portion centrally from a disk.

The support frame 17 that has the third surface 17c shaped as described above is fabricated by a machining process such as a cutting process. For example, a support frame 17 having a third surface 17c extending substantially perpendicularly to a first surface 17a may be prepared as a workpiece to be machined, and then cut along the third surface 17c to taper the third surface 17c into a shape inclined to the first surface 17a, thereby fabricating the support frame 17 illustrated in FIG. 2.

With the third surface 17c inclined as described above, the width of the opening 19, i.e., the length of the opening 19 along a direction parallel to the first surface 17a, or the diameter of the opening 19 providing the opening 19 is of a circular shape, is larger along the second surface 17b than along the first surface 17a.

The smaller the angle α formed between the third surface 17c and the first surface 17a, the easier it is for liquid such as a cleaning liquid to be discharged via the third surface 17c out of the frame unit 25 in a discharging step S3 to be described later. Specifically, the angle α should be 85° or smaller, preferably 75° or smaller, or more preferably 65° or smaller.

On the other hand, the larger the angle α formed between the third surface 17c and the first surface 17a, the less likely it is for the width of the support frame 17 to be extremely large in a case where the third surface 17c is inclined. It is thus possible to restrain the support frame 17 from increasing in size while the support frame 17 is allowed to keep a predetermined thickness. Specifically, the angle & should be 5° or larger, preferably 15° or larger, or more preferably 25° or larger.

In summary, it is preferable for the angle α to range from 5° to 85°, more preferable for the angle α to range from 15° to 75°, or much more preferable for the angle α to range from 25° to 65°.

In FIG. 2, the third surface 17c is illustrated as straight in cross section. However, the third surface 17c may be curved in cross section. In this case, the third surface 17c that is curved in cross section should be inclined to the first surface 17a such that the angle formed between a light tangent to the third surface 17c at a point closer to the second surface 17b than to the first surface 17a and the first surface 17a is large.

The film 21 is affixed to the first surface 17a of the support frame 17. The film 21 is of a laminated structure including a base and an adhesive layer, i.e., a glue layer, disposed on a surface of the base. The base is made of resin such as polyolefin, polyvinyl chloride, or polyethylene terephthalate, for example, whereas the adhesive layer is made of an epoxy-based adhesive, an acryl-based adhesive, or a rubber-based adhesive, for example. The adhesive layer may alternatively be made of an ultraviolet-curable resin that can be cured upon exposure to ultraviolet rays. The film 21 is not limited to the above details, and may be of another structure, for example, in the form of a thermocompression bonding sheet that is free of an adhesive layer and that can be bonded to the supported object 11 and the support frame 17 by way of thermocompression bonding.

The third surface 17c should preferably be treated to prevent liquids from remaining thereon. For example, the third surface 17c should be liquid-repellent. The third surface 17c that is liquid-repellent is effective to increase the angle of contact between liquid such as a cleaning liquid on the liquid-repellent third surface 17c and the liquid-repellent third surface 17c, allowing the liquid to be discharged easily in the discharging step S3. Specifically, the angle of contact between the liquid-repellent third surface 17c and the liquid thereon should be larger than 90°, preferably be larger than 110°, or more preferably be larger than 150°.

The third surface 17c may be made liquid-repellent by a material such as polytetrafluoroethylene (TPFE), titanium nitride (TiN), or diamond-like carbon (DLC), for example. The third surface 17c may be covered with PTFE by coating the third surface 17c with a coating agent containing PTFE and a dispersion medium and drying the coating agent. The third surface 17c may be covered with TiN or DLC by growing a TiN or DLC layer on the third surface 17c by way of chemical vapor deposition (CVD) or physical vapor deposition (PVD).

The third surface 17c may be lyophilic. The third surface 17c that is lyophilic is effective to reduce the angle of contact between liquid such as a cleaning liquid on the lyophilic third surface 17c and the lyophilic third surface 17c, allowing the liquid to be discharged easily out of the frame unit 25 along the third surface 17c. The angle of contact between the lyophilic third surface 17c and the liquid thereon should be 90° or smaller, preferably be 30° or smaller, or more preferably be 10° or smaller.

The third surface 17c may be made lyophilic by a material such as silicon dioxide (SiO₂) or titanium dioxide (TiO₂), for example. The third surface 17c may be covered with SiO₂ or TiO₂ by coating the third surface 17c with a coating agent containing SiO₂ or TiO₂ and a dispersion medium and drying the coating agent.

A material that makes the third surface 17c liquid-repellent or lyophilic may appropriately be selected depending on the material of the support frame 17. In addition to the third surface 17c, the second surface 17b may be made liquid-repellent or lyophilic. The second surface 17b that is liquid-repellent or lyophilic allows liquid such as a cleaning liquid that has flowed along the third surface 17c to be discharged easily out of the frame unit 25 along the second surface 17b. The first surface 17a should not be made liquid-repellent or lyophilic in order to prevent a reduction in the adhesive bonding between the support frame 17 and the film 21.

In addition, the third surface 17c should preferably have minute surface irregularities. The third surface 17c with minute surface irregularities is rendered liquid-repellent. As with the liquid-repellent material covering the third surface 17c, the minute surface irregularities on the third surface 17c allow liquid such as a cleaning liquid to be discharged easily out of the frame unit 25 along the third surface 17c.

Different surface treatment processes may be selected to form minute surface irregularities on the third surface 17c. For example, a sandblasting process may be performed on the third surface 17c to give the third surface 17c minute surface irregularities. In a case where the support frame 17 is made of aluminum, an anodizing process may be performed on the third surface 17c to give the third surface 17c minute surface irregularities.

In addition to the third surface 17c, the second surface 17b may have minute surface irregularities. The second surface 17b with minute surface irregularities allows liquid such as a cleaning liquid that has flowed along the third surface 17c to be discharged easily out of the frame unit 25 along the second surface 17b. The first surface 17a should not have minute surface irregularities in order to prevent a reduction in the adhesive bonding between the support frame 17 and the film 21.

A method of treating the supported object 11 that is supported on the support frame 17 by the film 21 according to the present embodiment will be described below. The method of treating the supported object 11 includes a frame unit forming step S1 of forming the frame unit 25 and a treating step S2 of treating the supported object 11. The method of treating the supported object 11 further includes the discharging step S3 of discharging liquid used in the treating step S2 and remaining on the supported object 11 out of the frame unit 25.

In the frame unit forming step S1, the frame unit 25 is formed. Specifically, the film 21 is affixed to the first surface 17a of the support frame 17 in covering relation to the opening 19. The supported object 11 is placed in the opening 19, and the film 21 is affixed to the supported object 11 by contacting the supported object 11. In this manner, the frame unit 25 is formed that includes the support frame 17, the film 21, and the supported object 11.

Then, the treating step S2 is carried out. According to the present embodiment, a treatment for cleaning the supported object 11 will be described as a treatment performed on the supported object 11 in the treating step S2. For example, after the frame unit forming step S1, a predetermined process such as a cutting process or a laser beam process is performed on the supported object 11 supported on the film-attached support frame 23 in a processing step. Thereafter, the supported object 11 while being supported on the film-attached support frame 23 is cleaned in the treating step S2. However, the treating step S2 is not limited to being carried out after the supported object 11 has been processed.

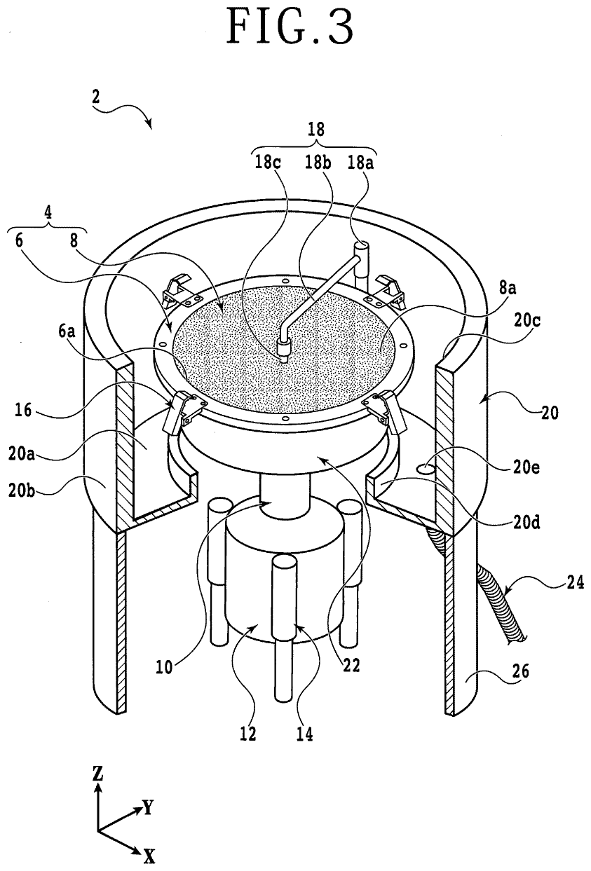

FIG. 3 illustrates a cleaning apparatus 2 in perspective. In FIG. 3, some components of the cleaning apparatus 2 are omitted from illustration for illustrative purposes. As illustrated in FIG. 3, the cleaning apparatus 2 includes a holding table, i.e., a spinner table, 4 for holding the frame unit 25 thereon. The holding table 4 includes a disk-shaped frame 6 made of ceramic or metal, for example. The frame 6 has a circular recess 6a defined in an upper surface thereof and having a circular opening that is open upwardly. The holding table 4 also includes a disk-shaped holding plate 8 complementarily fitted securely in the recess 6a.

The holding plate 8 is of a porous structure made of ceramic, for example. The holding plate 8 has an upper surface 8a for holding the second surface 11b of the supported object 11 thereon with the film 21 interposed therebetween. The upper surface 8a of the holding plate 8 that is fitted securely in the recess 6a lies substantially parallel to an X-axis and a Y-axis that extend horizontally and perpendicularly to each other. In FIG. 3, the X-axis is indicated by the arrow X and the Y-axis is indicated by the arrow Y, and a Z-axis that is indicated by the arrow Z extends vertically and perpendicularly to the X-axis and the Y-axis. The cleaning apparatus 2 is illustrated in reference to a three-dimensional XYZ coordinate system that includes the X-axis, the Y-axis, and the Z-axis.

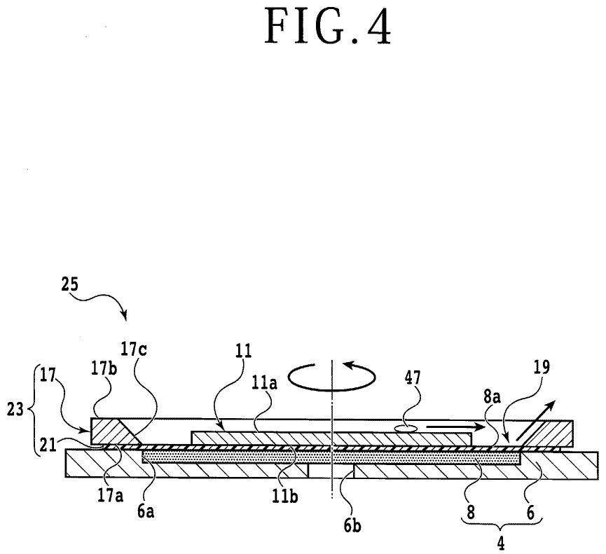

The frame 6 has a fluid channel 6b (see FIG. 4) defined therein that includes an upper end that is open at the bottom of the recess 6a. The fluid channel 6b has a lower end fluidly connected via a valve, not depicted, to a suction source, not depicted, such as an ejector, for example. When the suction source is actuated and the valve is open, a negative pressure generated by the suction source is transmitted through the valve, the fluid channel 6b, and the recess 6a and acts on the upper surface 8a of the holding plate 8.

While the frame unit 25 is being placed on the holding table 4 and the film 21 affixed to the first surface 17a of the support frame 17 is being held in contact with the upper surface 8a of the holding plate 8, when the negative pressure from the suction source acts on the upper surface 8a, the film 21 is attracted under suction to the upper surface 8a. The supported object 11 with the film 21 affixed thereto is thus held under suction on the holding table 4 with the first surface 11a facing upwardly.

As illustrated in FIG. 3, a rotary actuator 12 such as an electric motor is connected through a cylindrical spindle 10 to a lower central portion of the frame 6 of the holding table 4. When the rotary actuator 12 is energized, this rotates the spindle 10 about its own central axis substantially parallel to the Z-axis, rotating the holding table 4 about the central axis of the spindle 10. It is noted that the Z-axis is along a direction (vertical direction) perpendicular to the X-axis and the Y-axis.

A plurality of, i.e., three in the present embodiment, air actuators 14 are disposed around the rotary actuator 12 and have respective vertically movable parts fixed to the rotary actuator 12. When the air actuators 14 are operated, they lift and lower the rotary actuator 12, the spindle 10, and the holding table 4 along the Z-axis.

A plurality of, i.e., four in the present embodiment, presser mechanisms 16 for holding the frame unit 25 on the holding table 4 are mounted on a circumferential edge portion of the frame 6 of the holding table 4. The presser mechanisms 16 are angularly spaced at generally equal intervals around the holding table 4. The presser mechanisms 16 hold the frame unit 25 downwardly on the holding table 4 under centrifugal forces that are generated when the holding table 4 is rotated about the central axis. When the holding table 4 is rotated at a high speed about the central axis, the support frame 17 is pressed against the holding table 4 by the presser mechanisms 16, holding the frame unit 25 on the holding table 4.

As illustrated in FIG. 3, a liquid supply unit, i.e., a treating unit or a cleaning unit, 18 is disposed near the holding table 4. The liquid supply unit 18 includes a shank 18a vertically extending alongside of the holding table 4, an arm 18b extending from an upper end of the shank 18a radially inwardly over the upper surface 8a of the holding plate 8, and a nozzle, i.e., a liquid supply nozzle or a cleaning nozzle, 18c mounted on a tip end of the arm 18b. The shank 18a and the arm 18b include pipes, respectively, with fluid passages defined respectively therein for allowing liquid, i.e., a cleaning liquid, to flow therethrough. The nozzle 18c is fluidly connected through the arm 18b and the shank 18a to a liquid supply source, not depicted, that supplies the cleaning liquid through the shank 18a and the arm 18b to the nozzle 18c.

The liquid supply unit 18 also includes a rotary actuator, not depicted, for rotating the shank 18a about its central axis parallel to the Z-axis. When the rotary actuator is operated, this rotates the shank 18a about its central axis, causing the nozzle 18c to swing over the holding table 4. When the liquid supply source and the rotary actuator are operated, therefore, the nozzle 18c as it swings over the holding table 4 ejects the cleaning liquid toward the first surface 11a of the supported object 11 on the holding table 4. The cleaning liquid may typically include pure water, for example.

As illustrated in FIG. 3, the holding table 4 and the liquid supply unit 18 are housed in a space within a liquid receptacle 20. The liquid receptacle 20 includes a disk-shaped bottom wall 20a extending horizontally and a hollow cylindrical outer circumferential wall 20b extending along an outer circumferential edge of the bottom wall 20a and erected upwardly therefrom. The liquid receptacle 20 is thus of a bottomed hollow cylindrical shape with a circular opening 20c defined in its upper end.

The bottom wall 20a has a circular opening defined centrally therein, with the spindle 10 extending therethrough. The circular opening is surrounded by a hollow cylindrical inner circumferential wall 20d that protrudes upwardly and that is smaller in diameter and height than the outer circumferential wall 20b. When the cleaning apparatus 2 is in operation, the cleaning liquid ejected from the nozzle 18c impinges upon the supported object 11 held on the holding table 4 and scatters around. The cleaning liquid that has scattered around drops onto and stays on an area of the bottom wall 20a between the outer circumferential wall 20b and the inner circumferential wall 20d.

The bottom wall 20a has a drain hole 20e defined therein that extends thicknesswise through the bottom wall 20a. The drain hole 20e has a lower end joined to a drain hose 24. The cleaning liquid on the bottom wall 20a, i.e., the cleaning liquid that is collected in the liquid receptacle 20, is discharged through the drain hole 20e and the drain hose 24 out of the cleaning apparatus 2.

A tubular cover 22 that surrounds an upper portion of the spindle 10 is fixed to a lower portion of the holding table 4. The liquid receptacle 20 is supported on a plurality of legs 26 that extend downwardly from the liquid receptacle 20. The liquid receptacle 20 has its height adjusted to match the height of the holding table 4.

The cleaning apparatus 2 has one or more delivery mechanisms, not depicted, for delivering the frame unit 25 to the holding table 4. The delivery mechanism or mechanisms include a robot arm or robot arms, for example. The frame unit 25 is loaded to the holding table 4 by the delivery mechanism or mechanisms and placed on the holding table 4 with the first surface 11a of the supported object 11 facing upwardly. After the frame unit 25 has been cleaned, it is unloaded from the holding table 4 and delivered out of the cleaning apparatus 2 by the delivery mechanism or mechanisms.

Some of the various components of the cleaning apparatus 2 that have been described above are electrically connected to a controller, not depicted. The controller includes, for example, a computer including a processing device, not depicted, such as a central processing unit (CPU) and a storage device, not depicted, including a main storage unit such as a dynamic random access memory (DRAM) and/or an auxiliary storage unit such as a hard disk drive or a flash memory.

The processing device operates, by executing programs (software) stored in the storage device, to perform functions of the controller. The controller may be fully hardware-implemented rather than being software-implemented as described above.

In the treating step S2, the delivery mechanism or mechanisms of the cleaning apparatus 2 deliver the frame unit 25 to the holding table 4, and then the film 21 of the frame unit 25 is placed on the holding table 4 in contact with the upper surface 8a of the holding plate 8. Then, the suction source is actuated, and the valve is opened, transmitting the negative pressure from the suction source via the fluid channel 6b and the recess 6a to the holding plate 8. The negative pressure acts through the porous holding plate 8 on the upper surface 8a thereof. The film 21 of the frame unit 25 is now attracted under suction to the upper surface 8a of the holding plate 8. Therefore, the frame unit 25 is held under suction on the holding table 4 with the first surface 11a of the supported object 11 being exposed upwardly.

Thereafter, the controller moves the nozzle 18c over the frame unit 25, and controls the rotary actuator 12 to rotate the holding table 4 about its central axis while dropping the cleaning liquid from the nozzle 18c. At this time, the controller also energizes the rotary actuator coupled to the liquid supply unit 18 to cause the nozzle 18c to swing over the frame unit 25. The cleaning liquid is thus supplied to the first surface 11a of the supported object 11. The cleaning liquid supplied to the supported object 11 is spread radially outwardly toward the outer circumferential edge of the supported object 11 under centrifugal forces generated by the rotating supported object 11. As a result, the cleaning liquid flows radially outwardly along the first surface 11a of the supported object 11, washing away foreign matter such as swarf on the first surface 11a of the supported object 11. In this manner, the first surface 11a of the supported object 11 is cleaned.

The cleaning liquid thus spread radially outwardly toward the outer circumferential edge of the supported object 11 is scattered around radially outwardly off the frame unit 25 under the centrifugal forces from the frame unit 25. As illustrated in FIG. 2, the frame unit 25 has an annular slot defined between the supported object 11 and the support frame 17 by the outer circumferential edge of the supported object 11, the third surface 17c of the support frame 17, and the film 21. Therefore, the cleaning liquid tends to stay in the annular slot upon completion of the treating step S2.

Then, the discharging step S3 is carried out. FIG. 4 illustrates the frame unit 25 and other parts in the discharging step S3. In the discharging step S3, the controller controls the liquid supply unit 18 to stop dropping the cleaning liquid from the nozzle 18c and controls the rotary actuator 12 to rotate the holding table 4 about its central axis. At this time, the frame unit 25 is rotated about a vertical axis extending through the opening 19 in the support frame 17.

During rotation of the frame unit 25, the liquid, denoted by 47 in FIG. 4, remaining on the supported object 11 or the film 21 moves radially outwardly toward the support frame 17 under centrifugal forces generated by the rotating holding table 4. The liquid 47 is caused to flow along the third surface 17c and expelled radially outwardly of the support frame 17. The liquid 47 deposited on the supported object 11 or the film 21 is now discharged from the frame unit 25.

As described above, the liquid 47 is liable to stay in the annular groove, i.e., on the film 21, defined between the supported object 11 and the support frame 17. The frame unit 25 includes an annular step defined by the third surface 17c of the support frame 17 and the film 21. If the third surface 17c rose perpendicularly from the upper surface of the film 21, then the annular step would extend upright, tending to prevent the liquid 47 in the annular slot from being discharged therefrom.

According to the present embodiment, as illustrated in FIG. 4, the third surface 17c of the support frame 17 has a portion inclined to the first surface 17a such that the length of the opening 19 along a direction parallel to the first surface 17a is larger along the second surface 17b than along the first surface 17a. With the third surface 17c having a portion inclined to the first surface 17a, when the centrifugal forces generated by the rotation of the frame unit 25 act on the liquid 47 that exists between the supported object 11 and the support frame 17, causing the liquid 47 to reach the third surface 17c, the third surface 17c does not obstruct the movement of the liquid 47, and guides the liquid 47 to move therealong toward the outer circumferential edge of the support frame 17. Accordingly, the liquid 47 is prevented from staying in the vicinity of the third surface 17c, and is easily discharged along the third surface 17c.

Since the discharging of the liquid 47 from the frame unit 25 is accelerated as described above, the supported object 11 is prevented from having its appearance spoiled as the liquid 47 is not dried on the first surface 11a of the supported object 11 and hence does not leave blemishes thereon. If the liquid 47 is a liquid chemical such as an etching liquid, then the liquid 47 is prevented from eroding the film 21 by remaining on the film 21.

The cleaning apparatus 2 may further includes a gas supply unit for supplying a drying gas to the frame unit 25. For example, the gas supply unit includes a nozzle for ejecting a drying gas such as drying air. In the discharging step S3, the controller rotates the holding table 4 and controls the gas supply unit to eject the drying gas from the nozzle toward the frame unit 25. For example, the nozzle is positioned in overlying relation to the supported object 11 of the frame unit 25, and supplies the drying gas to the supported object 1. The drying gas that has reached the supported object 11 flows toward the outer circumferential edge of the frame unit 25, expelling the liquid 47 from the frame unit 25.

The treating step S2 and the discharging step S3 may be carried out respectively by different apparatuses. For example, the treating step S2 may be carried out on the frame unit 25 by the cleaning apparatus 2, and, after the frame unit 25 has been delivered from the cleaning apparatus 2 to a drying apparatus, the discharging step S3 may be carried out by the drying apparatus. If the supported object 11 is to be processed by a processing apparatus after the frame unit forming step S1, then the processing apparatus may incorporate the cleaning apparatus 2 therein. In this case, after the supported object 11 has been processed by the processing apparatus, the treating step S2 and the discharging step S3 are carried out by the cleaning apparatus 2 incorporated in the processing apparatus.

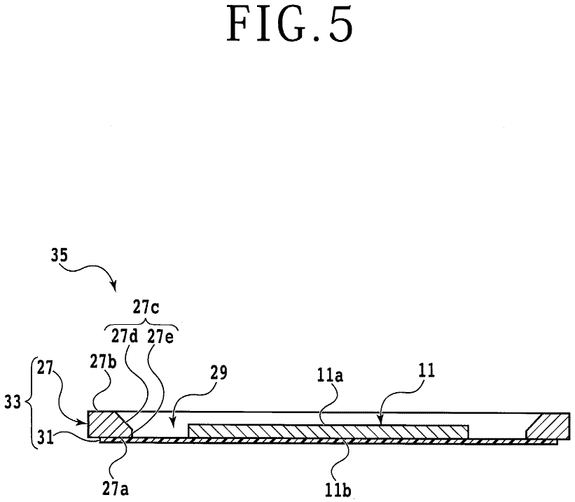

A second example of a frame unit 35 (see FIG. 5) will be described below. FIG. 5 illustrates, in cross section, the second example of the frame unit 35. As with the first example of the frame unit 25, the second example of the frame unit 35 includes a support frame 27 having an opening 29, a film 31, and the supported object 11. The support frame 27 and the film 31 make up a film-attached support frame 33. The support frame 27 has a third surface 27c, to be described below, that is different in shape from the third surface 17c of the support frame 17 of the first example of the frame unit 25.

As illustrated in FIG. 5, as with the support frame 17 of the first example of the frame unit 25, the support frame 37 has a first surface 27a, a second surface 27b opposite the first surface 27a, and a third surface 27c joined to both the first surface 27a and the second surface 27b. The third surface 27c defines the opening 29 and extends in surrounding relation thereto. The opening 29 extends through the support frame 27 and is open in both the first surface 27a and the second surface 27b.

The third surface 27c includes a portion, i.e., an inclined portion, 27d disposed closer to the second surface 27b and inclined to the first surface 27a and a portion, i.e., a vertical portion, 27e disposed closer to the first surface 27a and extending substantially perpendicularly to the first surface 27a. In other words, a part of the third surface 27c is inclined to the first surface 27a.

In order for the third surface 27c to be effective to discharge liquid such as a cleaning liquid easily out of the frame unit 35 in the discharging step S3, 50% or more of the third surface 27c should preferably be inclined to the first surface 27a. Stated otherwise, the area of the inclined portion 27d of the third surface 27c should preferably be equal to or larger than the area of the vertical portion 27e.

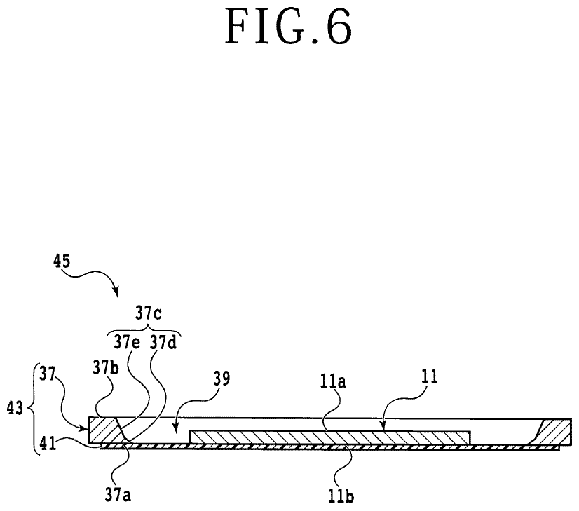

A third example of a frame unit 45 (see FIG. 6) will be described below. FIG. 6 illustrates, in cross section, the third example of the frame unit 45. As with the first example of the frame unit 25 and the second example of the frame unit 35, the third example of the frame unit 45 includes a support frame 37 having an opening 39, a film 41, and the supported object 11. The support frame 37 and the film 41 make up a film-attached support frame 43. The support frame 37 has a third surface 37c, to be described below, that is different in shape from the third surface 17c of the support frame 17 of the first example of the frame unit 25.

As illustrated in FIG. 6, as with the support frame 17 of the first example of the frame unit 25 and the support frame 27 of the second example of the frame unit 35, the support frame 37 has a first surface 37a, a second surface 37b opposite the first surface 37a, and a third surface 37c joined to both the first surface 37a and the second surface 37b. The third surface 37c defines the opening 39 and extends in surrounding relation thereto. The opening 39 extends through the support frame 37 and is open in both the first surface 37a and the second surface 37b.

The third surface 37c includes a first portion 37d disposed closer to the first surface 37a and a second portion 37e disposed closer to the second surface 37b. The angle formed between the first portion 37d and the first surface 37a and the angle formed between the second portion 37e and the first surface 37a are different from each other.

With respect to the third surface 37c of the support frame 37 illustrated in FIG. 6, the angle formed between the first portion 37d and the first surface 37a is smaller than the angle formed between the second portion 37e and the first surface 37a, i.e., the angle formed between a plane parallel to the first surface 37a and the second portion 37e. For example, the angle formed between the first portion 37d and the first surface 37a is in the range from 5° to 30°, whereas the angle formed between the second portion 37e and the first surface 37a is in the range from 60° to 85°.

Since the third surface 37c of the support frame 37 is made up of two portions having respective different angles of tilt, the third surface 37c makes it easier to discharge liquid such as a cleaning liquid out of the frame unit 25 when the discharging step S3 is carried out, while at the same time restraining the width of the support frame 37 from increasing. The third surface 37c of the support frame 37 may alternatively be made up of three or more portions that are inclined to the first surface 37a at respective different angles.

The structural and methodical details of the above embodiment may appropriately be changed or modified without departing from the scope of the invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A film-attached support frame comprising:
a metal support frame having an opening defined therein; and
a film affixed to the support frame in covering relation to the opening, wherein
the support frame includes
a first surface with which the film is in contact,
a second surface that is opposite to the first surface, and
a third surface joined to both the first surface and the second surface and surrounding the opening that is open in both the first surface and the second surface, and
the third surface has a portion inclined to the first surface such that a length of the opening along a direction parallel to the first surface is larger along the second surface than along the first surface.

2. The film-attached support frame according to claim 1, wherein
the portion includes a first portion closer to the first surface and a second portion closer to the second surface, and
an angle formed between the first portion and the first surface and an angle formed between the second portion and the first surface are different from each other.

3. The film-attached support frame according to claim 2, wherein the angle formed between the first portion and the first surface is smaller than the angle formed between the second portion and the first surface.

4. The film-attached support frame according to claim 1, wherein the third surface is liquid-repellent or lyophilic.

5. The film-attached support frame according to claim 2, wherein the third surface is liquid-repellent or lyophilic.

6. The film-attached support frame according to claim 3, wherein the third surface is liquid-repellent or lyophilic.

7. A metal support frame having an opening defined therein, comprising:
a first surface with which a film is to be in contact when in use;
a second surface that is opposite to the first surface; and
a third surface joined to both the first surface and the second surface and defining the opening that is open in both the first surface and the second surface, wherein
the third surface has a portion inclined to the first surface such that a length of the opening along a direction parallel to the first surface is larger along the second surface than along the first surface.

8. The support frame according to claim 7, wherein
the portion includes a first portion closer to the first surface and a second portion closer to the second surface, and
an angle formed between the first portion and the first surface and an angle formed between the second portion and the first surface are different from each other.

9. The support frame according to claim 8, wherein the angle formed between the first portion and the first surface is smaller than the angle formed between the second portion and the first surface.

10. The support frame according to claim 7, wherein the third surface is liquid-repellent or lyophilic.

11. The support frame according to claim 8, wherein the third surface is liquid-repellent or lyophilic.

12. The support frame according to claim 9, wherein the third surface is liquid-repellent or lyophilic.

13. A method of treating a supported object supported on a film using a support frame having an opening defined therein and including a first surface with which the film is to be in contact when in use, a second surface that is opposite to the first surface, and a third surface joined to both the first surface and the second surface and defining the opening that is open in both the first surface and the second surface, the method comprising:
a frame unit forming step of forming a frame unit including the support frame, the film, and the supported object by affixing the film to the first surface of the support frame in covering relation to the opening and affixing the film to the supported object disposed in the opening, wherein the third surface of the support frame has a portion inclined to the first surface such that a length of the opening along a direction parallel to the first surface is larger along the second surface than along the first surface;
after the frame unit forming step, a treating step of treating the supported object with liquid by supplying the liquid to the supported object; and
after the treating step, a discharging step of discharging the liquid remaining on the supported object or the film under centrifugal forces by rotating the frame unit about an axis extending through the opening.

14. A method of treating a supported object supported on a film using a support frame having an opening defined therein and including a first surface with which the film is to be in contact when in use, a second surface that is opposite to the first surface, and a third surface joined to both the first surface and the second surface and defining the opening that is open in both the first surface and the second surface, the method comprising:
a frame unit forming step of forming a frame unit including the support frame, the film, and the supported object by affixing the film to the first surface of the support frame in covering relation to the opening and affixing the film to the supported object disposed in the opening, wherein the third surface of the support frame has a portion inclined to the first surface such that a length of the opening along a direction parallel to the first surface is larger along the second surface than along the first surface, the portion includes a first portion closer to the first surface and a second portion closer to the second surface, and an angle formed between the first portion and the first surface and an angle formed between the second portion and the first surface are different from each other;
after the frame unit forming step, a treating step of treating the supported object with liquid by supplying the liquid to the supported object; and
after the treating step, a discharging step of discharging the liquid remaining on the supported object or the film under centrifugal forces by rotating the frame unit about an axis extending through the opening.

15. A method of treating a supported object supported on a film using a support frame having an opening defined therein and including a first surface with which the film is to be in contact when in use, a second surface that is opposite to the first surface, and a third surface joined to both the first surface and the second surface and defining the opening that is open in both the first surface and the second surface, the method comprising:
a frame unit forming step of forming a frame unit including the support frame, the film, and the supported object by affixing the film to the first surface of the support frame in covering relation to the opening and affixing the film to the supported object disposed in the opening, wherein the third surface of the support frame has a portion inclined to the first surface such that a length of the opening along a direction parallel to the first surface is larger along the second surface than along the first surface, the portion includes a first portion closer to the first surface and a second portion closer to the second surface, an angle formed between the first portion and the first surface and an angle formed between the second portion and the first surface are different from each other, and the angle formed between the first portion and the first surface is smaller than the angle formed between the second portion and the first surface;
after the frame unit forming step, a treating step of treating the supported object with liquid by supplying the liquid to the supported object; and
after the treating step, a discharging step of discharging the liquid remaining on the supported object or the film under centrifugal forces by rotating the frame unit about an axis extending through the opening.
